(19) United States
(12) Patent Application Publication
(10) Pub. No.: US 2007/0152289 A1
(43) Pub. Date: Jul. 5, 2007

(54) Avalanche photodetector with reflector-based responsivity enhancement

(76) Inventors: Michael T. Morse, San Jose, CA (US); Ansheng Liu, Cupertino, CA (US); Gadi Sarid, Tel Aviv (IL); Alexandre Pauchard, Chatel-St-Denis (CH)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/322,514

(22) Filed: Dec. 30, 2005

(51) Int. Cl. H01L 27/14; H01L 31/00

(52) U.S. Cl. 257/431

(57) ABSTRACT

An avalanche photodetector is disclosed. An apparatus according to aspects of the present invention includes an absorption region including a first type of semiconductor. The first type of semiconductor material has a graded doping concentration of a dopant material within the absorption region. A multiplication region is proximate to and separate from the absorption region. The multiplication region includes a second type of semiconductor material in which there is an electric field. The electric field is to multiply the free charge carriers created in the absorption region. A reflector is disposed proximate to the multiplication region such that the multiplication region is between the absorption region and the reflector. The reflector is to reflect unabsorbed light that reaches the reflector from the absorption region back to the absorption region.

### BACKGROUND OF THE INVENTION

1. Field of the Invention

Embodiments of invention relate generally to optical devices and, more specifically but not exclusively relate to photodetectors.

2. Background Information

The need for fast and efficient optical-based technologies is increasing as Internet data traffic growth rate is overtaking voice traffic pushing the need for fiber optical communications. Transmission of multiple optical channels over the same fiber in the dense wavelength-division multiplexing (DWDM) system provides a simple way to use the unprecedented capacity (signal bandwidth) offered by fiber optics. Commonly used optical components in the system include wavelength division multiplexed (WDM) transmitters and receivers, optical filter such as diffraction gratings, thin-film filters, fiber Bragg gratings, arrayed-waveguide gratings, optical add/drop multiplexers, lasers, optical switches and photodetectors. Photodiodes may be used as photodetectors to detect light by converting incident light into an electrical signal. An electrical circuit may be coupled to the photodetector to receive the electrical signal representing the incident light. The electrical circuit may then process the electrical signal in accordance with the desired application. Avalanche photodetectors provide internal electrical gain and therefore have high sensitivity suitable for very weak optical signal detection.

### BRIEF DESCRIPTION OF THE DRAWINGS

Non-limiting and non-exhaustive embodiments of the present invention are described with reference to the following figures, wherein like reference numerals refer to like parts throughout the various views unless otherwise specified.

FIG. 1 is a diagram illustrating an example of a cross-section view of an avalanche photodetector including reflector-based enhancement in a system in accordance with the teachings of the present invention.

FIG. 2 is a diagram illustrating an energy band structure of an example of avalanche photodetector including reflector-based enhancement in accordance with the teachings of the present invention.

FIG. 3 is a diagram illustrating reflectivity versus buried oxide thickness relationships for various wavelengths of light in an avalanche photodetector including reflector-based enhancement in accordance with the teachings of the present invention.

### DETAILED DESCRIPTION

Methods and apparatuses for avalanche photodetectors (APDS) with enhanced responsivity are disclosed. In the following description numerous specific details are set forth in order to provide a thorough understanding of the present invention. It will be apparent, however, to one having ordinary skill in the art that the specific detail need not be employed to practice the present invention. In other instances, well-known materials or methods have not been described in detail in order to avoid obscuring the present invention.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment. Furthermore, the particular features, structures or characteristics may be combined in any suitable manner in one or more embodiments. In addition, it is appreciated that the figures provided herewith are for explanation purposes to persons ordinarily skilled in the art and that the drawings are not necessarily drawn to scale. Moreover, it is appreciated that the specific example doping concentrations, thicknesses and materials or the like that are described in this disclosure are provided for explanation purposes and that other doping concentrations, thicknesses and materials or the like may also be utilized in accordance with the teachings of the present invention.

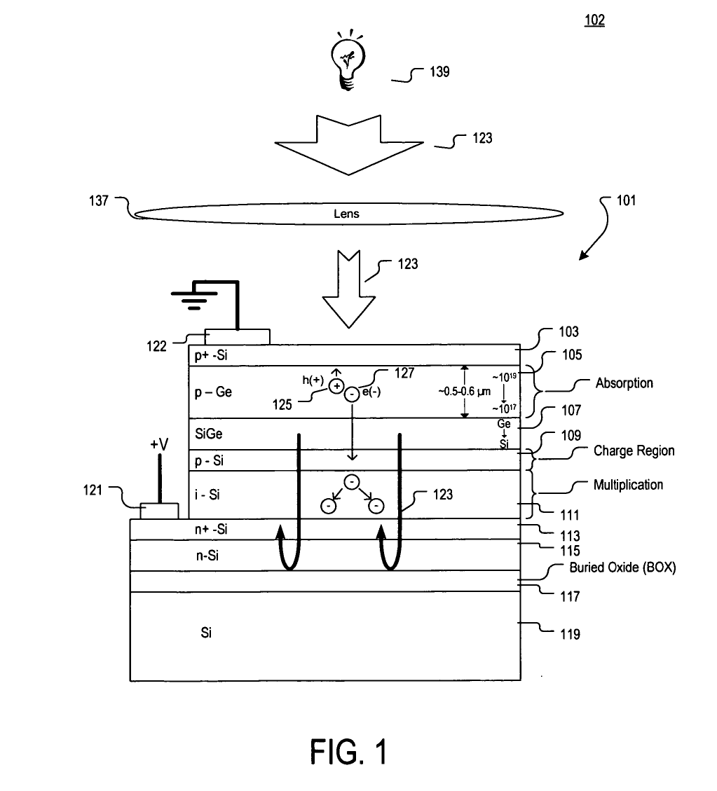

FIG. 1 is a diagram illustrating generally a cross-section view of a system 102 including an avalanche photodetector (APD) 101 according to an example of the present invention. In the illustrated example, light or an optical beam 123 is directed from an optical source 139 to APD 101. Depending on the specific application, optical beam 123 may originate from or may be reflected from optical source 139. In one example, optical beam 123 may optionally be directed or focused from optical source 139 directly to APD 101 or may be directed through an optical element 137 to APD 101.

It is appreciated that one or more APDs 101 may be used in a variety of applications and configurations. For instance, depending on the specific application, it is appreciated that APD 101 may be employed individually to for example detect a signal encoded in optical beam 123 in telecommunications. In another example, APD 101 may be one of a plurality of APDs arranged in an array or grid to sense images or the like. For example, an array APD's arranged in a grid may function to sense images, similar to a complementary metal oxide semiconductor (CMOS) sensor array or the like.

In one example, optical element 137 may include a lens or other type of refractive or diffractive optical element such that an image is directed or focused on array of APDs 101 with illumination including optical beam 123. Optical beam 123 may include visible light, infrared light and/or a combination of wavelengths across the visible through infrared spectrum having wavelengths of 800 nm to 1500 nm or the like.

In the illustrated example, APD 101 is a unitraveling carrier (UTC) photodiode with separate absorption and multiplication (SAM) regions and exhibits internal photodetector gain. In one example, APD 101 includes a plurality of layers of semiconductor materials including for example silicon (Si), Germanium (Ge) and oxide. As shown in the depicted cross-section, layer 103 is the “top” layer and includes p+ doped Si. A layer 105, which is the absorption region of APD 101, is next to layer 103. In the illustrated example APD 101, the absorption region or layer 105 is a bit thinner than some other common APDs, which will enables APD 101 to support higher bandwidths since there isn't as high an electric field in layer 105 compared to other common APDs. As will be discussed, the lower responsivity of having a thinner absorption region or layer 105 in APD 101 is addressed later in accordance with the teachings of the present invention.

In the specific example illustrated in FIG. 1, layer 105 is approximately 0.6 μm thick and includes p doped Ge and is doped with a dopant material such as boron. As shown, the doping concentration of layer 105 is approximately linearly increased going from “bottom” to “top” with example doping concentrations of approximately 10¹⁷ to approximately 10¹⁹. The gradient or increasing doping concentration of layer 105 creates a small built-in electric field within the absorption region in accordance with the teachings of the present invention.

As shown in FIG. 1, an interface layer 107 is between layer 105 and a charge region including layer 109. Layer 109 includes p-Si and the interface layer includes SiGe. In the illustrated example, there is a gradient Si and Ge material in layer 107 such that there is a higher concentration of Ge in layer 107 towards the p-Ge of layer 105 and there is a higher concentration of Si in layer 107 towards the p-Si of layer 109.

As shown in the example, a multiplication region including a layer 111 disposed next to the charge region of layer 109. The doping concentration and layer thickness of layer 109 are properly chosen so that a high electrical field is obtained in layer 111. In the illustrated example, layer 111 of the multiplication region includes intrinsic Si and is separate from and proximate to layer 105 of the absorption region. As shown, layer 113 of n+ doped Si is next to layer 109 and then a layer 115 including n doped Si is next to layer 109. As shown, a reflective layer is 117 is next to layer 115 in one example according to the teachings of the present invention. In the illustrated example, layer 117 is a buried oxide layer disposed between layer 115 and layer 119, which in one example is a Si substrate of a silicon-on-insulator (SOI) wafer.

As shown in the example depicted in FIG. 1, an external reverse bias voltage is applied to APD 101 with a positive voltage+V applied to n+-Si layer 113 through contact 121 and with p+-Si layer 103 grounded through contact 122. In one example, a high electric field is created in the multiplication region in layer 111 as a result of the reverse biasing of APD 101 with the application of positive voltage+V to contact 121 and with contact 122 grounded as shown.

In operation, optical beam 123 is incident upon layer 103 of APD 101. Optical beam 123 propagates through layer 103 and into layer 105 of the absorption region or the APD 101. For one example, the p-Ge material of layer 105 absorbs a portion of the light of optical beam 123, which photo-generates electron-hole pairs, which are shown in FIG. 1 as holes 125 and electrons 127. As shown in FIG. 1, the electric field due to applied voltage and the linear doping of boron in the p-Ge of layer 105 accelerates the photo-generated electrons 125 in layer 105 of the absorption region down towards the multiplication region layer 111. The acceleration of the photo-generated carriers helps to improve the bandwidth and response time of APD 101 in accordance with the teachings of the present invention.

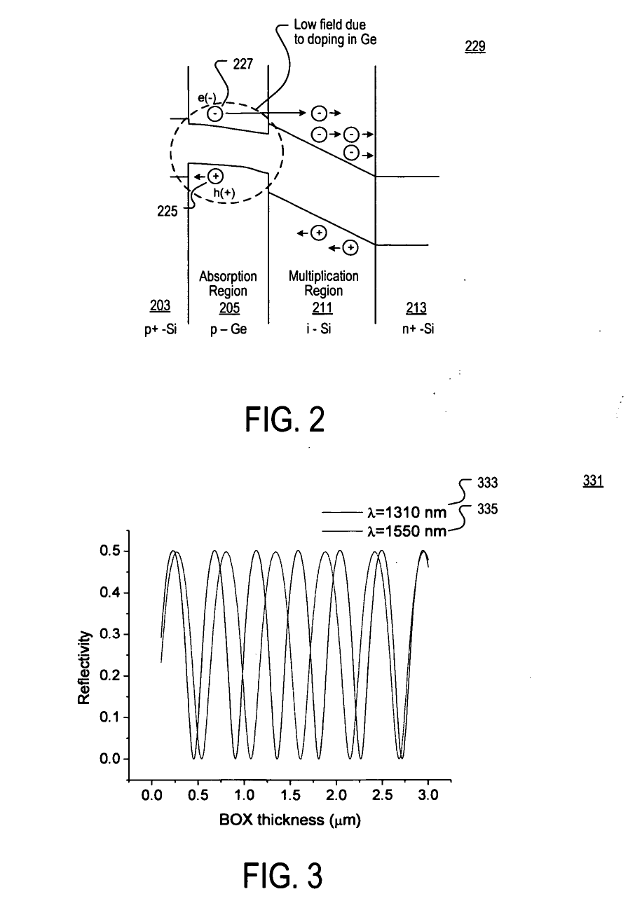

The gradient or increasing doping concentration of layer 105 that creates the small built-in electric field in the absorption region mentioned above reduces the electrical field at the heterointerface between the Ge of the absorption region and the Si of the multiplication region due to the doping of the Ge. To illustrate, FIG. 2 shows generally a diagram that illustrates the energy band structure for an example of avalanche photodetector such as APD 101. As shown, an electron-hole pair, including electron 227 and hole 225, is generated in the absorption region 205. With the doping in the Ge of absorption region 205 as discussed in FIG. 1, the electrical field in the absorption region 205 and at the heterointerface between absorption region 205 and multiplication region 211 is relatively weak as compared to the field in the multiplication region 211 in accordance with the teachings of the present invention. This lowered electric field at the interface between the Ge and the Si is significant because of the high concentration of dislocations, which will become sources of dark current and gain hystersis, especially at high electrical fields. Furthermore, defects at the sidewalls of etched Ge are also problematic so lowering the electric field as discussed is also important there.

Referring back to FIG. 1, due to the biasing resulting from the applied voltages, doping concentrations and electric fields present in the APD 101 as discussed above, the holes 125 generated in layer 105 of the absorption region drift towards layer 103 and the electrons 127 are accelerated towards layer 111 of the multiplication region. As the electrons 127 drift into the multiplication region, the electrons are subjected to a relatively high electric field in intrinsic Si of layer 111 resulting from the doping levels of the neighboring layers of p-doped silicon in layer 109 and n+ doped silicon in layer 113. As a result of the high electric field in layer 111, impact ionization occurs to the electrons 127 that drift into the multiplication region from the absorption region in accordance with the teachings of the present invention. Therefore, the photocurrent created from the absorption of optical beam 123 in the absorption region is multiplied or amplified in multiplication region in accordance with the teachings of the present invention. The photocarriers are then collected at contacts 121 and 122. For instance holes 125 may be collected at contact 122 and electrons 127 are collected at contact 121. Contacts 121 and 122 may be coupled to electrical circuitry to process the signals present at each of the contacts 121 and 122 according to embodiments of the present invention.

As mentioned, layer 109 includes SiGe, which in the illustrated example has a material gradient such that there is a higher concentration of Ge near the Ge of layer 105 and that there is a higher concentration of Si near the Si of layer 109. As such, the stress between the Ge of layer 105 and the Si of layer 109 is reduced in accordance with the teachings of the present invention. It is appreciated that the Ge-Si interface would be populated with a high concentration of misfit dislocations because of the lattice constant mismatch between Ge and Si, which can have a deleterious effect on device performance of APD 101, especially at high fields. In addition, in one example, there is high doping in the Ge of layer 105 of the absorption region, which helps to prevent the built-in electric field from reaching through the SiGe interface, which further reduces the stress at the weak link between the Ge and the Si in accordance with the teachings of the present invention.

For longer wavelengths of optical beam 123 of for example γ> 1000 nm, a portion of the light of optical beam 123 may propagate through layer 105 of absorption region unabsorbed. Indeed, as mentioned above, layer 105 has a relatively thin thickness of for example −0.5 to −0.6 μm, which helps to achieve high bit rates of near 10 Gbps or greater. In other words, a tradeoff of having the relatively thin absorption region for increased bandwidth is that there is lower absorption or responsivity in APD 101.

In order to compensate for the relatively thin layer 105 of the absorption region, which increases device speed, a reflector is defined proximate to layer 115 such that layer 115 of the multiplication region is disposed between layer 105 of the absorption region and the reflector in accordance with the teachings of the present invention. In the illustrated example, the buried oxide layer 117 defines a Si-SiO₂ interface, which defines a reflector that reflects optical beam 123 as shown FIG. 1. The unabsorbed portion of light of optical beam 123 from the absorption region that reaches the reflector formed at the buried oxide layer is then reflected back into layer 105 of the absorption region for another pass to create additional electron-hole pairs or photocurrent in accordance with the teachings of the present invention. This additional pass of the unabsorbed light from optical beam 123 back into layer 105 increases the responsivity of APD 101 in accordance with the teachings of the present invention.

FIG. 3 is a diagram illustrating 331 generally reflectivity versus buried oxide thickness relationships for various wavelengths of light in an avalanche photodetector including reflector-based enhancement in accordance with the teachings of the present invention. As shown in the diagram 331, line 333 shows the reflectivity versus buried oxide thickness of an optical beam having a wavelength of γ=1310 nm and line 335 shows the reflectivity versus buried oxide thickness of an optical beam having a wavelength of γ=1550 nm. As shown, greater than ˜45-50% reflectivity can be obtained for both wavelengths of γ=1310 nm and γ=1550 nm using a standard 3 μm buried oxide (BOX) SOI wafers in accordance with the teachings of the present invention. In another example, a reflective coating, such as for example a metal layer, may be disposed below layer 115 to provide a reflector in accordance with the teachings of the present invention. For instance, an APD on a silicon wafer without a buried oxide (BOX) layer could be used by coating the APD with a metal to give even higher reflectivity in accordance with the teachings of the present invention. Accordingly, unabsorbed light that propagates through the absorption region in the first pass is reflected back into the absorption for another pass where the unabsorbed light will have another opportunity to be absorbed, which will improve and enhance responsivity of the APD in accordance with the teachings of the present invention.

The above description of illustrated embodiments of the invention, including what is described in the Abstract, is not intended to be exhaustive or to be limitation to the precise forms disclosed. While specific embodiments of, and examples for, the invention are described herein for illustrative purposes, various equivalent refinements and modifications are possible, as those skilled in the relevant art will recognize. Indeed, it is appreciated that the specific wavelengths, dimensions, materials, times, voltages, power range values, etc., are provided for explanation purposes and that other values may also be employed in other embodiments in accordance with the teachings of the present invention.

These modifications can be made to embodiments of the invention in light of the above detailed description. The terms used in the following claims should not be construed to limit the invention to the specific embodiments disclosed in the specification and the claims. Rather, the scope is to be determined entirely by the following claims, which are to be construed in accordance with established doctrines of claim interpretation.

What is claimed is:

1. An apparatus, comprising:
an absorption region including a first type of semiconductor, the first type of semiconductor material having a gradient doping concentration of a dopant material within the absorption region;
a multiplication region proximate to and separate from the absorption region, the multiplication region including a second type of semiconductor material in which there is an electric field to multiply the free charge carriers created in the absorption region; and
a reflector disposed proximate to the multiplication region such that the multiplication region is between the absorption region and the reflector, the reflector to reflect unabsorbed light that reaches the reflector from the absorption region back to the absorption region.

2. The apparatus of claim 1 wherein the first type of semiconductor comprises germanium and the second type of semiconductor material comprises silicon.

3. The apparatus of claim 2 further comprising an interface layer disposed between the absorption region and the multiplication region, the interface layer having a material gradient of germanium and silicon.

4. The apparatus of claim 2 wherein the dopant material comprises boron.

5. The apparatus of claim 1 wherein the reflector is defined at an interface between the second type of semiconductor material and an oxide.

6. The apparatus of claim 5 wherein the oxide comprises a buried oxide layer of a silicon-on-insulator wafer.

7. The apparatus of claim 1 wherein the reflector comprises a reflective coating.

8. A method, comprising:
directing an optical beam into including a first type of semiconductor material of an absorption region of an avalanche photodetector having a gradient doping concentration;
absorbing a portion of the optical beam to photo-generate electron-hole pairs in the absorption region;
accelerating electrons from the absorption region into a second type of semiconductor material of a multiplication region of the avalanche photodetector;
multiplying in the multiplication region the electrons from the absorption region; and
reflecting an unabsorbed portion of the optical beam that reaches a reflector proximate to the multiplication region back to the absorption region.

9. The method of claim 8 further comprising absorbing the reflected unabsorbed portion of the optical beam reflected from the reflector to photo-generate electron-hole pairs in the absorption region.

10. The method of claim 8 further comprising applying an external bias voltage to the avalanche photo detector to create a high electric field in the multiplication region.

11. The method of claim 10 wherein multiplying the electrons form the absorption region comprises impact ionizing the electrons from the absorption region with the high electric field in the multiplication region.

12. The method of claim 10 wherein applying the external bias voltage to the avalanche photodetector to create the high electric field in the multiplication region comprises reverse biasing the avalanche photodetector.

13. The method of claim 8 wherein accelerating the electrons from the absorption region into the second type of semiconductor material of the multiplication region comprises directing the electrons though an interface layer disposed between the absorption region and the multiplication region, the interface layer having a material gradient of first type of semiconductor material and the second type of semiconductor material.

14. The method of claim 8 accelerating the electrons from the absorption region into the second type of semiconductor material of the multiplication region comprises accelerating the electrons from the absorption region into the multiplication region with an electric field in the avalanche photodetector.

15. A system, comprising:
one or more avalanche photodetectors, each of the one or more avalanche photodetectors including:
an absorption region including a first type of semiconductor, the first type of semiconductor material having a gradient doping concentration of a dopant material within the absorption region;
a multiplication region proximate to and separate from the absorption region, the multiplication region including a second type of semiconductor material in which there is an electric field to multiply the free charge carriers created in the absorption region; and
a reflector disposed proximate to the multiplication region such that the multiplication region is between the absorption region and the reflector, the reflector to reflect unabsorbed light that reaches the reflector from the absorption region back to the absorption region; and
an optical element to direct an optical beam onto the one or more avalanche photodetectors.

16. The system of claim 15 wherein the optical element comprises a lens.

17. The system of claim 15 wherein the first type of semiconductor comprises germanium and the second type of semiconductor material comprises silicon.

18. The system of claim 17 wherein each of the one or more avalanche photodetectors further comprises an interface layer disposed between the absorption region and the multiplication region, the interface layer having a material gradient of germanium and silicon.

19. The system of claim 17 wherein the dopant material comprises boron.

20. The system of claim 17 wherein the reflector is defined at an interface between the second type of semiconductor material and a buried oxide layer of a silicon-on-insulator wafer.
